(19) United States
(12) Patent Application Publication
(10) Pub. No.: US 2013/0046484 A1
(43) Pub. Date: Feb. 21, 2013

(54) DATA PROCESSING FOR HYPERPOLARIZED XENON MAGNETIC RESONANCE IN THE LUNG

(71) Applicants: Yulin Chang, St. Louis, MO (US); Jason C. Woods, St. Louis, MO (US)

(72) Inventors: Yulin Chang, St. Louis, MO (US); Jason C. Woods, St. Louis, MO (US)

(21) Appl. No.: 13/587,633

(22) Filed: Aug. 16, 2012

Related U.S. Application Data
(60) Provisional application No. 61/525,419, filed on Aug. 19, 2011.

(51) Int. Cl. G06F 19/00; G01R 23/16

(52) U.S. Cl. 702/24; 324/318

(57) ABSTRACT

Embodiments quantify gas exchange in a lung using a model that results in two related expressions, which account for normalized amplitudes of two dissolved-Xenon signals in the lung at a given gas-exchange time. One of the two dissolved-Xenon signals is from Xenon in lung tissue and blood plasma, which resonates at about 197 ppm from the free-Xenon frequency in the air space. The other is from Xenon in the red blood cells, which resonates at about 217 ppm for human but is species dependent.

### CROSS REFERENCE TO RELATED APPLICATION

This application claims priority to U.S. provisional patent application No. 61/525,419 filed Aug. 19, 2011, which is incorporated herein in its entirety.

### STATEMENT REGARDING FEDERALLY SPONSORED RESEARCH & DEVELOPMENT

This invention was made with government support under grant number 2R4HL087550-04A1 awarded by the National Institute of Health. The government has certain rights in the invention.

### BACKGROUND

Gas exchange is the essential function of a lung and almost all pulmonary diseases can be attributed to a deficient gas exchange in the lung or a deficiency in the delivery of a gas to the lung. At least some known imaging techniques may be used to measure various parameters and/or conditions of the lung. For example, computerized tomography (CT) measures tissue density within the lung and magnetic resonance imaging (MRI) of hyperpolarized Helium-3 (³He) within the lung can provide images of the air spaces in the lung. However, such imaging techniques are unable to provide a direct measurement of gas exchange in the lung.

In contrast, a known technique of MR of hyperpolarized Xenon-129 (¹²⁹Xe) is capable of providing direct measurements of gas exchange in the lung. A particular feature of Xenon that permits a quantified understanding of lung function is that Xenon dissolved into a human lung exhibits two large chemical shifts from the resonance frequency of the free Xenon gas. One shift is at 197 ppm, for Xenon in lung tissue and blood plasma (TP Xenon), and the other shift is at 217 ppm for Xenon in the red blood cells (RBC xenon).

The subsequent gas exchange can be observed by either measuring the attenuation of the gas-phase Xenon signal, often referred to as Xenon polarization transfer contrast (XTC), or by measuring the growth of the dissolved-Xenon signals, which goes by the name of uptake, replenishment, or chemical shift saturation recovery (CSSR). The XTC procedure, however, is indirect and is usually time-consuming This limits the range of exchange time. In contrast, the CSSR method directly measures the increase of the dissolved-Xenon signal (relative to the gas signal) after saturation and can therefore be easily performed at fine increments of exchange time. Nonetheless, there has not been a theory or model using CSSR that is able to interpret Xenon uptake dynamics for both dissolved-Xenon peaks in the lung.

### BRIEF DESCRIPTION

In an embodiment, a computing device generally comprises a communication interface that is configured to receive at least one spectroscopic signal representative of hyperpolarized Xenon gas that is dissolved within lung tissue, blood plasma, and/or red blood cells. The spectroscopic signal resonates at a frequency of at 197 ppm and/or 217 ppm. A processor is coupled to the communication interface and programmed to calculate at least one value that corresponds to a normalized amplitude of the spectroscopic signal at a given gas-exchange time. A presentation interface is coupled to the processor and configured to display at least one output representative of the value to a user to enable a determination of a plurality of parameters related to gas exchange in the lung.

In another embodiment, a system for use in quantifying gas exchange in a lung generally comprises a magnetic resonance imaging device (MRI) and a computing device coupled to the MRI. The MRI is configured to generate at least one spectroscopic signal representative of hyperpolarized Xenon gas that is dissolved within lung tissue, blood plasma, and/o red blood cells. The spectroscopic signal resonates at a frequency of 197 ppm and/or 217 ppm. The computing device includes a communication interface that is configured to receive the spectroscopic signal. A processor is coupled to the communication interface and programmed to calculate at least one value that corresponds to a normalized amplitude of the spectroscopic signal at a given gas-exchange time. A presentation interface is coupled to the processor and configured to display at least one output representative of the value to a user to enable a determination of a plurality of parameters related to gas exchange in the lung.

In yet another embodiment, a method for quantifying gas exchange in a lung is provided. At least one spectroscopic signal representative of hyperpolarized Xenon gas that is dissolved within lung tissue, blood plasma, and/or red blood cells is received via a communication interface. The spectroscopic signal resonates at a frequency of 197 ppm and/or 217 ppm. At least one value that corresponds to a normalized amplitude of the spectroscopic signal at a given gas-exchange time is calculated via a processor. At least one output that is representative of the value is displayed to a user, via a presentation interface, to enable a determination of a plurality of parameters related to gas exchange in the lung.

### BRIEF DESCRIPTION OF THE DRAWINGS

FIG. 1 is a block diagram of an exemplary system for use in quantifying gas exchange in a lung.

FIG. 2 is a block diagram of an exemplary computing device that may be used with the system shown in FIG. 1.

FIG. 3 is a schematic diagram of a lung septum.

FIG. 4 is a schematic diagram of a lung septum with blood flow.

FIG. 5 is an exemplary method for use in quantifying gas exchange in a lung using the computing device shown in FIG. 2.

FIG. 6 is an exemplary graphical representation of a Xenon signal in tissue and blood plasma for a normal human lung.

FIGS. 7A-7D are exemplary graphical representations of a Xenon signal in tissue and blood plasma for a human lung under different physiological conditions than a normal human lung.

FIG. 8 is an exemplary graphical representation of a Tissue+Plasma-Xenon signal and Red Blood Cell-Xenon signal amplitudes versus exchange time.

FIG. 9 is an exemplary graphical representation of the dissolved-Xenon spectra in the real and imaginary channels in a human lung.

### DETAILED DESCRIPTION

Embodiments described herein measure or quantify gas exchange in a lung using hyperpolarized Xenon gas by interpreting Xenon uptake dynamics for at least one dissolved-Xenon peaks in the lung. More specifically, the embodiments quantify gas exchange in a lung using a model that results in two related expressions, which account for normalized amplitudes of two dissolved-Xenon signals in the lung at a given gas-exchange time. One of the two dissolved-Xenon signals is from Xenon in lung tissue and blood plasma, which resonates at about 197 ppm from the free-Xenon frequency in the air space. The other is from Xenon in the red blood cells, which resonates at about 217 ppm for human but is species dependent.

For the calculation in some embodiments, a model of gas exchange for hyperpolarized ¹²⁹Xe in the lung may be used. The model includes two expressions and characterizes uptake of Xenon at two different resonance frequencies. The two expressions are governed by the following five pulmonary parameters: the surface-area-to-volume ratio, barrier-to-septum ratio (ratio between air-blood barrier thickness and septal thickness), hematocrit, gas-exchange time constant, and pulmonary capillary transit time. The model offers a simple interpretation of existing data of Xenon magnetic resonance in the lung and the model is also consistent with the existing known theory of Xenon uptake. The model is demonstrated in a calculation that is sensitive to various functional and structural changes of the lung, and is, therefore, potentially useful in the screening for a variety of pulmonary diseases.

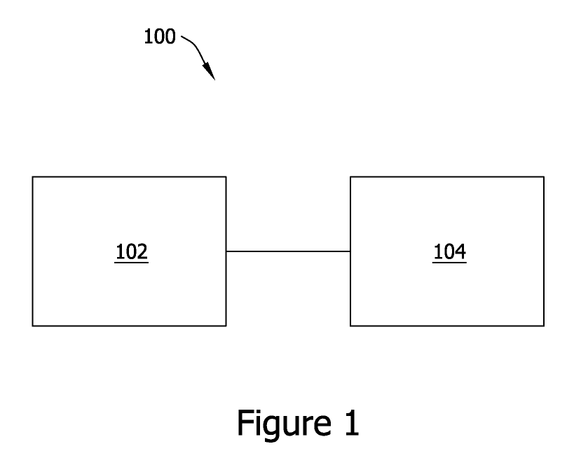

FIG. 1 is an exemplary system 100 for use in quantifying gas exchange in a lung, such as a human lung. System 100 includes a magnetic resonance imaging device (MRI) 102. The contrast used with MRI 102 includes a hyperpolarized gas, such as hyperpolarized Xenon gas, and more particularly, hyperpolarized ¹²⁹Xe. MRI 102 is configured to generate at least one spectroscopic signal representative of hyperpolarized ¹²⁹Xe within the lung. In an exemplary embodiment, MRI 102 may be an open or closed MRI and is sized such that a patient may fit therein. While MRI 102 is shown in system, the present disclosure is not limited to any one particular type of imaging technique or device, and one of ordinary skill in the art will appreciate that the current disclosure may be used in connection with any other type of imaging technique or device that enables system 100 to function as described herein.

System 100 further includes a computing device 104 communicatively coupled to MRI 102. It should be noted that, as used herein, the term “couple” is not limited to a direct mechanical, electrical, and/or communication connection between components, but may also include an indirect mechanical, electrical, and/or communication connection between multiple components. In an exemplary embodiment, MRI 102 may communicate with computing device 104 using a wired network connection (e.g., Ethernet or an optical fiber), a wireless communication means, such as radio frequency (RF), e.g., FM radio and/or digital audio broadcasting, an Institute of Electrical and Electronics Engineers (IEEE®) 802.11 standard (e.g., 802.11(g) or 802.11(n)), the Worldwide Interoperability for Microwave Access (WIMAX®) standard, a short-range wireless communication channel such as BLUETOOTH®, a cellular phone technology (e.g., the Global Standard for Mobile communication (GSM)), a satellite communication link, and/or any other suitable communication means. IEEE is a registered trademark of the Institute of Electrical and Electronics Engineers, Inc., of New York, N.Y. WIMAX is a registered trademark of WiMax Forum, of Beaverton, Oreg. BLUETOOTH is a registered trademark of Bluetooth SIG, Inc. of Kirkland, Wash.

In an exemplary embodiment, computing device 104 is configured to receive at least one spectroscopic signal representative of hyperpolarized ¹²⁹Xe within the lung. The spectroscopic signals may be at various amplitudes, such as 197 ppm and 217 ppm.

During operation, MRI 102 uses a magnetic field to align the magnetization of some atoms in the body and radio frequency fields to systematically alter the alignment of this magnetization. As such, rotating magnetic fields are produced and detectable by a scanner (not shown) within MRI 102. More specifically, in an exemplary embodiment, MRI 102 generates at least one spectroscopic signal representative of hyperpolarized ¹²⁹Xe within the lung. The signal(s) are transmitted to computing device 104 and, as explained in more detail below, computing device 104 calculates at least one parameter related to an exchange of hyperpolarized ¹²⁹Xe in the lung based on the spectroscopic signal(s) received by computing device 104. Computing device 104 calculates the parameter(s) by comparing the spectroscopic signal(s) with a period of time for a dispersion of hyperpolarized ¹²⁹Xe within the lung. The computing device presents the parameters to a user.

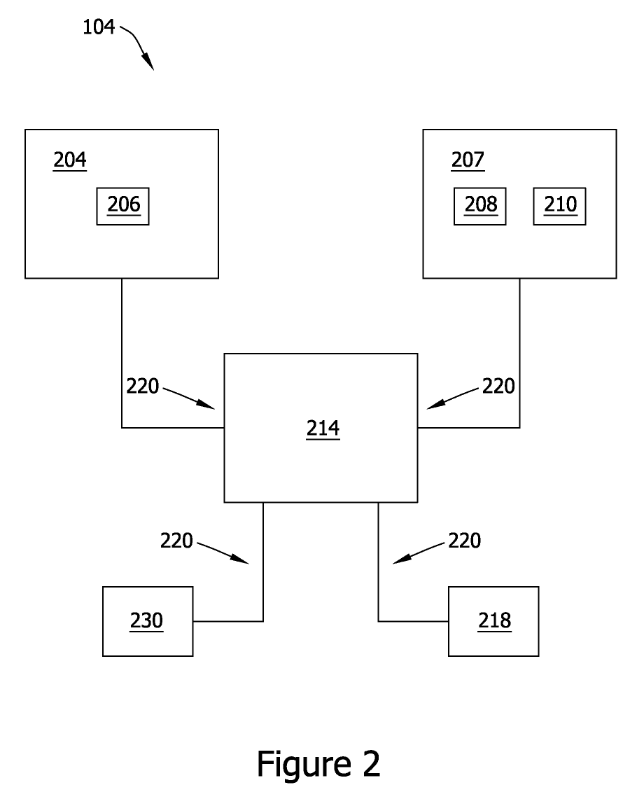

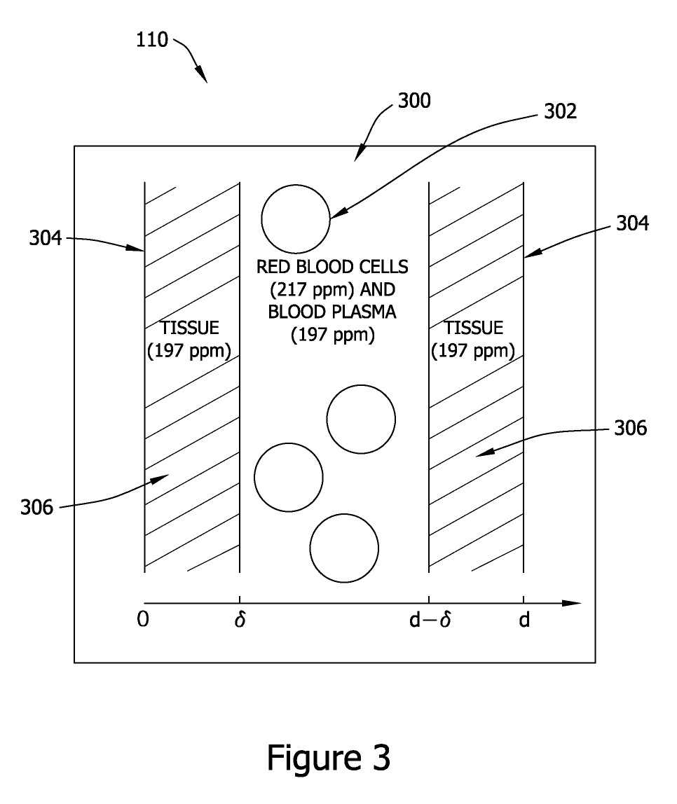

FIG. 2 is a block diagram of computing device 104. In an exemplary embodiment, computing device 104 includes a user interface 204 that receives at least one input from a user, such as an operator of MRI 102 (shown in FIG. 1). FIG. 3 is a schematic diagram of a lung septum 110. Referring to FIG. 2, user interface 204 may include a keyboard 206 that enables the user to input pertinent information. User interface 204 may also include, for example, a pointing device, a mouse, a stylus, a touch sensitive panel (e.g., a touch pad or a touch screen), a gyroscope, an accelerometer, a position detector, and/or an audio input interface (e.g., including a microphone).

Moreover, in an exemplary embodiment, computing device 104 includes a presentation interface 207 that presents information, such as input events and/or validation results, to the user. Presentation interface 207 may also include a display adapter 208 that is coupled to at least one display device 210. More specifically, in an exemplary embodiment, display device 210 may be a visual display device, such as a cathode ray tube (CRT), a liquid crystal display (LCD), an organic LED (OLED) display, and/or an “electronic ink” display. Alternatively, presentation interface 207 may include an audio output device (e.g., an audio adapter and/or a speaker) and/or a printer.

Computing device 104 also includes a processor 214 and a memory device 218. Processor 214 is coupled to user interface 204, presentation interface 207, and to memory device 218 via a system bus 220. In an exemplary embodiment, processor 214 communicates with the user, such as by prompting the user via presentation interface 207 and/or by receiving user inputs via user interface 204. The term “processor” refers generally to any programmable system including systems and microcontrollers, reduced instruction set circuits (RISC), application specific integrated circuits (ASIC), programmable logic circuits (PLC), and any other circuit or processor capable of executing the functions described herein. The above examples are exemplary only, and thus are not intended to limit in any way the definition and/or meaning of the term “processor.”

In an exemplary embodiment, memory device 218 includes one or more devices that enable information, such as executable instructions and/or other data, to be stored and retrieved. Moreover, memory device 218 includes one or more computer readable media, such as, without limitation, dynamic random access memory (DRAM), static random access memory (SRAM), a solid state disk, and/or a hard disk. In an exemplary embodiment, memory device 218 stores, without limitation, application source code, application object code, configuration data, additional input events, application states, assertion statements, validation results, and/or any other type of data. Computing device 104, in an exemplary embodiment, may also include a communication interface 230 that is coupled to processor 214 via system bus 220. Moreover, communication interface 230 is communicatively coupled to MRI 102.

In an exemplary embodiment, processor 214 may be programmed by encoding an operation using one or more executable instructions and providing the executable instructions in memory device 218. In an exemplary embodiment, processor 214 is programmed to calculate at least one parameter related to an exchange of hyperpolarized Xenon gas, such as hyperpolarized ¹²⁹Xe, in the lung based on at least one spectroscopic signal received from MRI 102. Processor 214 is programmed to calculate the parameter(s) by comparing the spectroscopic signal(s) with a period of time for a dispersion of the hyperpolarized Xenon gas within the lung.

More specifically, a model of gas exchange in the lung for Xenon gas which takes into account an uptake of dissolved Xenon gas at both 197 ppm and 217 ppm is utilized. This model first calculates the normalized dissolved-Xenon signal amplitudes in the tissue barrier and blood separately. The blood-Xenon signal is then divided into signals from RBC Xenon (217 ppm) and plasma Xenon (197 ppm) based on hematocrit in the blood. Finally, the tissue Xenon and the plasma Xenon are combined (TP Xenon) for their common chemical shift. The model uses as coefficients the following pulmonary parameters: surface-to-volume ratio (SVR) of the lung, the ratio between the barrier thickness and the total septal thickness (barrier-to-septal ratio, or BSR), Xenon-exchange time constant (T), Xenon partition coefficient in the red blood cells (RBCs) (η), and the pulmonary capillary transit time (t_{X}). Since these parameters provide a comprehensive description of the lung, the presented model can be used for simultaneous quantification of lung function, physiology, and microstructure.

A simplified 1-dimensional geometry of lung microstructure is known and has been previously used. The total septal thickness is d and the barrier thickness is δ, as shown in FIG. 3. The diffusion equation, as shown in Equation 1 below, for dissolved-Xenon density M_{d} within the septum, perpendicular to the blood flow is considered

$$\frac{\partial {M}_{d}}{\partial t} = D \frac{{\partial }^{2} {M}_{d}}{\partial {x}^{2}} , \qquad ( 1 )$$

subject to the initial condition as shown in Equation 2 below

M_{d}(x, 0)=0, x ε (0, d), (2)

and the boundary conditions as shown in Equation 3 below.

M_{d}(0, t)=M_{d}(d, t)=λM_{f}. (3)

In the above Equations 1-3, M_{f} is the density of free Xenon gas (at 0 ppm) in the air spaces, D is the diffusion coefficient of dissolved Xenon, and λ is the Ostwald solubility of Xenon in lung septum 110.

The solution of this problem is a well-known sum of infinite series (n>0) as shown in Equation 4 below,

$${M}_{d} ( x , t ) = λ {M}_{f} ( 1 - \frac{4}{π} {\sum }_{n = odd} \frac{1}{n} sin \frac{n π x}{d} {e}^{- {n}^{2} t / T} ) , \qquad ( 4 )$$

where T is the Xenon-exchange time constant in the lung, as shown in Equation 5 below.

$$T = \frac{{d}^{2}}{{π}^{2} D} . \qquad ( 5 )$$

In order to obtain a measurable quantity in an MR experiment, M_{d}(x, t) is converted into the “signal distribution” S_{d}(x, t) normalized by the signal of free Xenon gas in the lung. If S_{A} and V_{g} are the total surface area and total volume of the air spaces in the lung, respectively, and since the dissolved-Xenon signal is proportional to M_{d}(x, t)SA/2, and the free-Xenon-gas signal is proportional to MfVg, the normalized signal distribution S_{d}(x, t) for dissolved Xenon can be written as Equation 6 below.

$${S}_{d} ( x , t ) = \frac{λ}{2} \frac{{S}_{A}}{{V}_{g}} ( 1 - \frac{4}{π} {\sum }_{n = odd} \frac{1}{n} sin \frac{n π x}{d} {e}^{- {n}^{2} t / T} ) , \qquad ( 6 )$$

In Equation 6, S_{A}/V_{g} is the surface-area-to-volume ratio, or SVR. As described herein, the term “dissolved-Xenon signal” will mean the signal of dissolved-Xenon normalized by the corresponding gas-phase Xenon signal.

The dissolved-Xenon signal from each compartment in the lung is then considered. As shown in FIG. 3, a simplified geometry that assumes a layer of tissue, or air-blood barrier, of thickness δ (δ<d/2) at each side of septum 110 is used. The total signal from the tissue, denoted by S_{d1}(t), can be calculated as the spatial integral of S_{d} in Equation 6 over the two regions from 0 to δ and from d−δ to d and as shown in Equation 7 below.

$$\begin{matrix}{S}_{d 1} ( t ) = \frac{λ d}{2} \frac{{S}_{A}}{{V}_{g}} [ \frac{2 δ}{d} - \frac{8}{{π}^{2}} {\sum }_{n = odd} \frac{1}{{n}^{2}} ( 1 - cos \frac{n π δ}{d} ) {e}^{- {n}^{2} t / T} ] \\ = b [ \frac{2 δ}{d} - \frac{8}{{π}^{2}} {\sum }_{n = odd} \frac{1}{{n}^{2}} ( 1 - cos \frac{n π δ}{d} ) {e}^{- {n}^{2} t / T} ] ,\end{matrix} \qquad ( 7 )$$

As illustrated in FIG. 3, lung septum 110 includes capillary blood 300, that includes RBCs 302 and air-blood barriers 304. Barriers 304 are formed by several layers of tissue membranes 306. The total septal thickness is d, and the barrier thickness δ. For humans, Xenon dissolved into lung tissue and plasma (TP Xenon) has a chemical shift of 197 ppm, and Xenon dissolved into RBCs 302 (RBC Xenon) has a chemical shift of 217 ppm, both from the resonance frequency of free Xenon gas in alveolar spaces (not shown in FIG. 3).

Equation 8, as shown below,

$$b = \frac{λ d}{2} \frac{{S}_{A}}{{V}_{g}} \qquad ( 8 )$$

is the normalization factor (dimensionless), and δ/d is called barrier-to-septum ratio, or BSR. The dissolved-Xenon signal from the blood (“blood Xenon”) is more difficult to calculate due to the flow effect. If there was no flow, the signal from the static blood, S_{d2s}(t), could simply be calculated as the spatial integral of S_{d} over the region from δ to d−δ, as shown in Equation 9 below.

$${S}_{d 2 s} ( t ) = b [ ( 1 - \frac{2 δ}{d} ) - \frac{8}{{π}^{2}} {\sum }_{n = odd} \frac{1}{{n}^{2}} cos \frac{n π δ}{d} {e}^{- {n}^{2} t / T} ] . \qquad ( 9 )$$

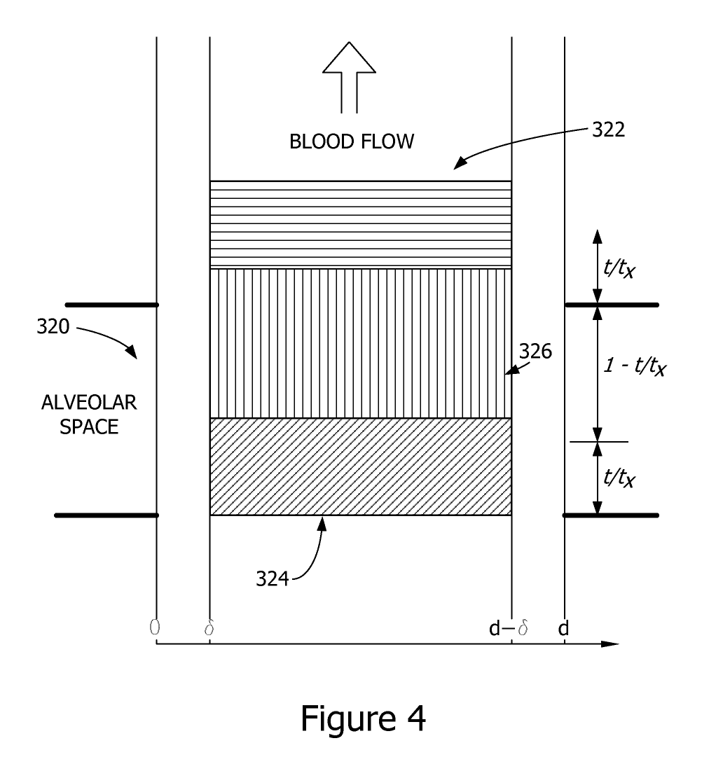

FIG. 4 is a schematic diagram of lung septum 110 with blood flow. Due to flow, a fraction of dissolved-Xenon in the blood has exchange time less than t. To deal with this “partial time” effect, known methods may be used. If τ is the time a certain infinitesimally thin layer of blood spends in the gas-exchange zone, the signal contribution from blood Xenon in this layer is, in terms of S_{d2s}, S_{d2s}(τ)dτ/t_{X}, where t_{X} is the pulmonary capillary transit time, defined as the average time an RBC spends in the gas-exchange zone (i.e., regions in contact with alveolar spaces 320 in the lung. Therefore, the total contribution of the “partial-time volume”, shown as the two outer regions 322 and 324, can be calculated by using a time integral over S_{d2s}, from 0 to t. On the other hand, for t<t_{X}, (1−t/t_{X}) fraction of blood (middle region 326) is always in contact with the gas-exchange zone during exchange time t, thus Xenon signal within this section can still be treated as static.

As illustrated in FIG. 4, assuming t_{X} is the pulmonary capillary transit time defined as the average time an RBC spent in the gas-exchange zone and t (t<t_{X}) is the exchange time under study, then two outer regions 322 and 324 of t/t_{X} of blood will only experience exchange time less than t due to flow. Middle region 326 or the portion of (1−t/t_{X}) can be treated as static with exchange time t. The flow effect is known in the art and has been previously investigated. The calculation taking the flow effect into account is in Equation 10 below, and is also the total Xenon from the blood.

$$\begin{matrix}{S}_{d 2} ( t ) = 2 {\int }_{0}^{t} \frac{d τ}{{t}_{X}} {S}_{d 2 s} ( τ ) + ( 1 - \frac{t}{{t}_{X}} ) {S}_{d 2 s} ( t ) \\ = 2 b [ ( 1 - \frac{2 δ}{d} ) \frac{t}{{t}_{X}} - \frac{8}{{π}^{2}} \frac{T}{{t}_{X}} {\sum }_{n = odd} \frac{1}{{n}^{4}} cos \frac{n π δ}{d} ( 1 - {e}^{- {n}^{2} t / T} ) ] + \\ b ( 1 - \frac{t}{{t}_{X}} ) [ ( 1 - \frac{2 δ}{d} ) - \frac{8}{{π}^{2}} {\sum }_{n = odd} \frac{1}{{n}^{2}} cos \frac{n π δ}{d} {e}^{- {n}^{2} t / T} ] .\end{matrix} \qquad ( 10 )$$

In order to calculate the Xenon signal in tissue and blood plasma, e.g., TP Xenon signal S_{TP}(t) at 197 ppm and signal of RBC Xenon S_{RBC}(t) at 217 ppm, let η denote the fraction of RBC Xenon relative to total Xenon in blood. This calculation is shown in Equation 11 below

$$\begin{matrix}{S}_{TP} ( t ) = {S}_{d 1} ( t ) + ( 1 - η ) {S}_{d 2} ( t ) \\ = b [ \frac{2 δ}{d} - \frac{8}{{π}^{2}} {\sum }_{n = odd} \frac{1}{{n}^{2}} ( 1 - cos \frac{n π δ}{d} ) ) {e}^{- {n}^{2} t / T} ] + 2 b ( 1 - η ) \\ [ ( 1 - \frac{2 δ}{d} ) \frac{t}{{t}_{X}} - \frac{8}{{π}^{2}} \frac{T}{{t}_{X}} {\sum }_{n = odd} \frac{1}{{n}^{4}} cos ( \frac{n π δ}{d} ) ( 1 - {e}^{- {n}^{2} t / T} ) ] + \\ b ( 1 - η ) ( 1 - \frac{t}{{t}_{X}} ) [ ( 1 - \frac{2 δ}{d} ) - \frac{8}{{π}^{2}} {\sum }_{n = odd} \frac{1}{{n}^{2}} cos ( n π κ ) {e}^{- {n}^{2} t / T} ] ,\end{matrix} \qquad ( 11 )$$

and is shown in Equation 12 below

$$\begin{matrix}{S}_{RBC} ( t ) = η {S}_{d 2} ( t ) \\ = 2 b η [ ( 1 - \frac{2 δ}{d} ) \frac{t}{{t}_{X}} - \frac{8}{{π}^{2}} \frac{T}{{t}_{X}} {\sum }_{n = odd} \frac{1}{{n}^{4}} cos ( \frac{n π δ}{d} ) ( 1 - {e}^{- {n}^{2} t / T} ) ] + \\ b η ( 1 - \frac{t}{{t}_{X}} ) [ ( 1 - \frac{2 δ}{d} ) - \frac{8}{{π}^{2}} {\sum }_{n = odd} \frac{1}{{n}^{2}} cos ( \frac{n π κ}{d} ) {e}^{- {n}^{2} t / T} ] .\end{matrix} \qquad ( 12 )$$

The hematocrit (Hct) can be calculated from η using Equation 13 below.

$$Hct = \frac{η / {λ}_{RBC}}{η / {λ}_{RBC} + ( 1 - η ) / {λ}_{P}} , \qquad ( 13 )$$

As shown in Equation 13, λ_{RBC} and λ_{P} are Ostwald solubilities of Xenon in RBCs and plasma, respectively. From these equations, it can be seen that as the order of a term becomes higher, its weight becomes smaller, and the “apparent” time constant becomes shorter as well. For example, the mth term has an order of n=2m−1, its corresponding time constant is shown below in Equation 14.

$${T}_{n} = \frac{T}{{n}^{2}} = \frac{T}{{( 2 m - 1 )}^{2}} . \qquad ( 14 )$$

Since T is the only meaningful parameter to measure out of all Tₙ, it is called the principle time constant to distinguish from those of higher-order terms.

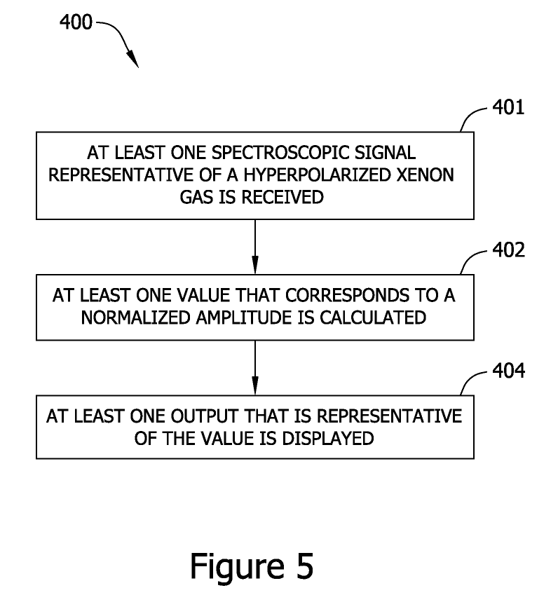

FIG. 5 illustrates an exemplary method 400 for quantifying gas exchange in a lung. At least one spectroscopic signal representative of a hyperpolarized Xenon gas, such as hyperpolarized ¹²⁹Xe, that is dissolved within the lung, such as lung tissue, blood plasma, and red blood cells, is received 401, via a communication interface, such as communication interface 230 (shown in FIG. 2). At least one value that corresponds to a normalized amplitude of the spectroscopic signal at a given gas-exchange time is calculated 402, via a processor, such as processor 214 (shown in FIG. 2) based on the spectroscopic signal(s). At least one output that is representative of the value is presented 406 to a user via a presentation interface, such as presentation interface 207 (shown in FIG. 2).

Moreover, upon calculating the parameters discussed above, processor 214 may generate an output, such as a graphical plot, to present to the user. More specifically, S_{TP}(t) and S_{RBC}(t) may be plotted using GNUPLOT up to 700 ms, which is consistent with previous known CSSR experiments. In order to numerically plot the functions, the infinite series are truncated at the fifth term, i.e., the terms with n=11 and higher are discarded. This is a reasonable truncation since the longest time constant previously found was less than 80 ms. Thus, the shortest time constant represented by the truncated expressions are shorter than 1 ms, which is below the limit that can be measured with the existing setup and available data. The following parameters from various known studies are used for plots of Xenon uptake in a healthy human lung: λ≈0.2, d≈10 μm, SVR≈250 cm⁻¹, δ≈2 μm, T≈40 ms, η=0.5, t_{X}≈1.6 s. In order to observe how sensitive the Xenon uptake curves are to pathological changes, S_{TP}(t) and S_{RBC}(t) are also plotted using parameters corresponding to different pathological or physiological changes: SVR≈150 cm⁻¹ for reduced SVR in COPD/emphysema; δ≈3 μm for thickening of barrier in pulmonary fibrosis; η≈0.3 for reduced Hct in anemia; t_{X}≈0.8 s for the increased pumping power of a heart after mild exercise.

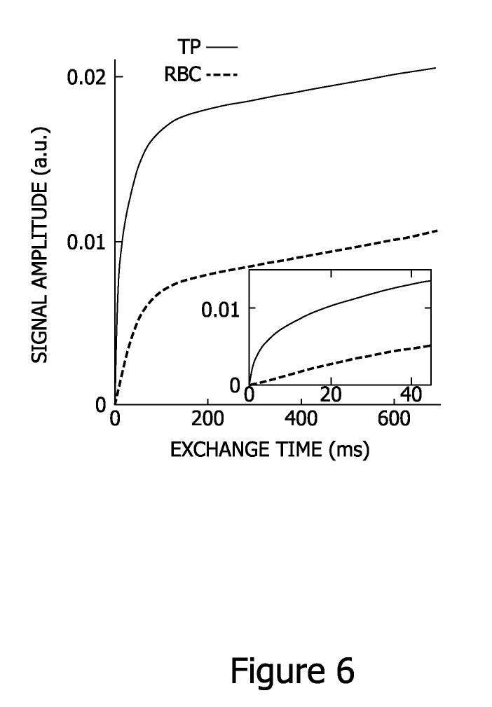

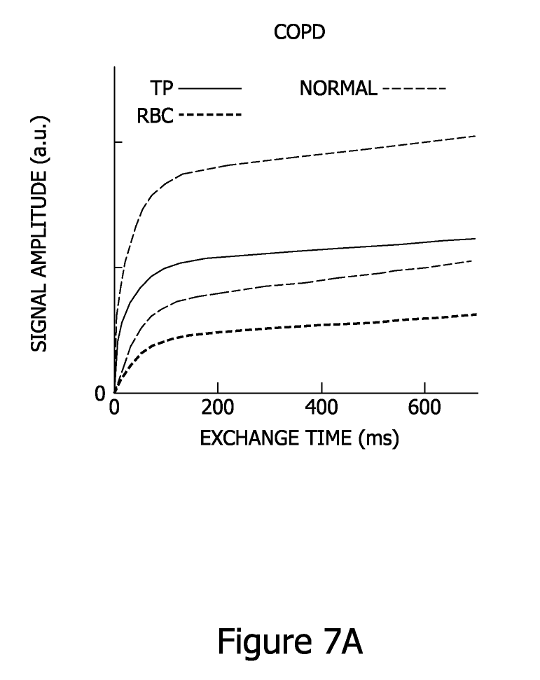

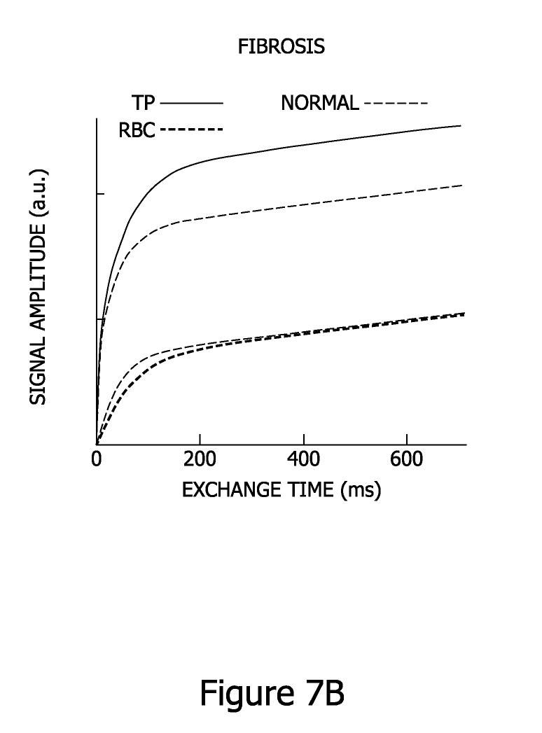

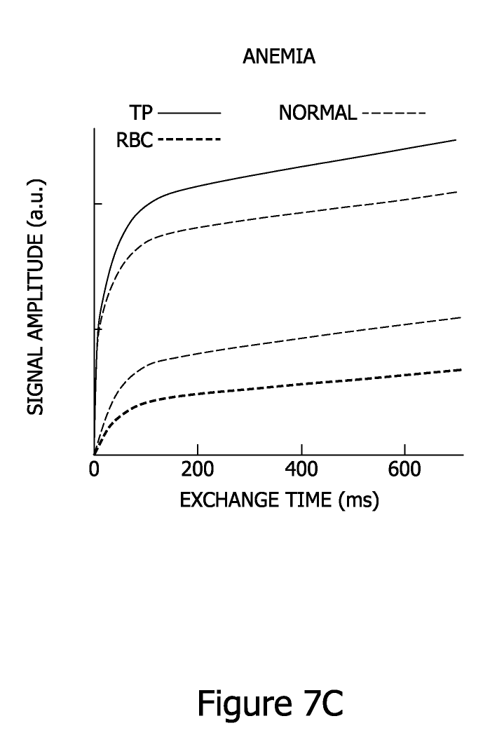

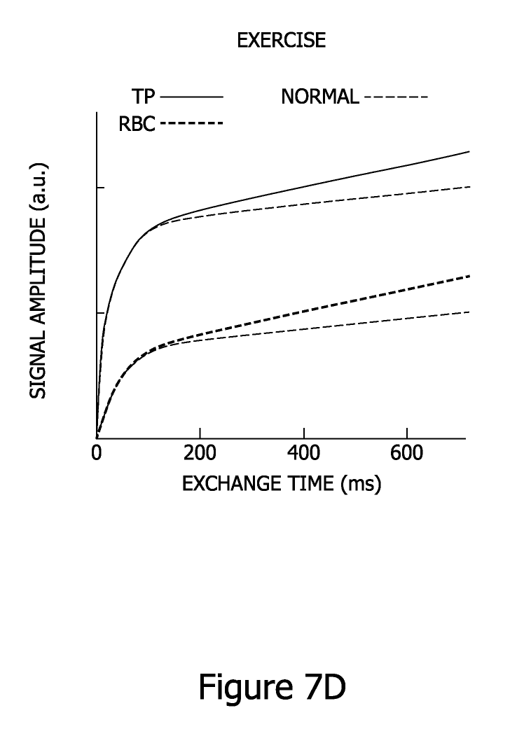

FIG. 6 illustrates a graphical representation of a Xenon signal in tissue and blood plasma and, more particularly, S_{TP}(t) and S_{RBC}(t) in Equations 11 and 12, respectively, for n≦9, as functions of the gas-exchange time up to 700 ms for a normal human lung. The parameters used are: b=0.025, =δ 2 μm, d=10 μm, η=0.5, T=40 ms, and t_{X}=1.6 s. The inset shows details of the curves at short exchange times. FIGS. 7A-7D illustrate a graphical representation of S_{TP}(t) and S_{RBC}(t) in a lung under different pathological and physiological conditions. A COPD/emphysema patient often has lower surface area, hence lower SVR (150 cm in this case), in the lung, which results in reduced signals of both S_{TP}(t) and S_{RBC}(t). Fibrotic lungs, due to thickening δ≈3 μm or scarring of the barrier, are characterized by elevated S_{TP}(t) as well as prolonged time constant due to increased overall septal thickness (12 μm in this case); in anemic patients S_{RBC}(t) is significantly lower due to low hematocrit (η=0.3 in this case); the enhanced heart pumping power during exercise leads to a shorter t_{X} (t_{X}=0.8 s in this case), which is responsible for the more rapid growths of both S_{TP}(t) and S_{RBC}(t) after xenon saturation in lung parenchyma.

The uptake curves of normal lung were reproduced in each plot for comparison. The reduced signals of S_{TP}(t) and S_{RBC}(t) in COPD/emphysema patients due to loss of lung surface area, were expected and consistent with the results previously published and known results. Fibrotic lungs are characterized by elevated S_{TP}(t) as well as prolonged time constant due to increased overall septal thickness, which is supported by previously published and known results. It is known that the enhanced heart pumping power during exercise will cause t_{X} to be shorter, which is responsible for the more rapid growths of both S_{TP}(t) and S_{RBC}(t) after Xenon saturation in lung parenchyma.

The ability to directly measure gas exchange gives Xenon a substantial advantage over proton and Helium in lung MRI. The model represented by Equations 11 and 12 provides a detailed characterization of the Xenon exchange processes in the lung. Its validity can be verified by comparing the two expressions to existing data in previously published and known studies. For example, the plots of S_{TP}(t) and S_{RBC}(t) in FIG. 6 have indeed all the important features in previously published data. Specifically, S_{TP}(t) rises more rapidly in the short exchange-time regime than S_{RBC}(t) because the barrier compartment is in direct contact of the gas-phase Xenon. S_{TP}(t) and S_{RBC}(t) are saturated at almost the same time since they share the same time constant and S_{TP}(t) is always higher than S_{RBC}(t) since S_{TP} contains both the tissue and plasma compartments. However, the growth rates of S_{TP}(t) and S_{RBC}(t) after saturation are only determined by blood flow. In addition to a comparison with the existing data, the model can also be validated by comparing the model to the single-peak model developed by previously known studies. Since the single-peak model ignored the barrier compartment, by setting δ=0 in both Equations 11 and 12 and adding S_{TP}(t) to S_{RBC}(t) (or, equivalently, by simply setting δ=0 and η=1 for S_{RBC}(t) in Equation (12)), the single-peak model should be recovered. A simple calculation would show that by doing so, the expression for the dynamics of entire dissolved-Xenon in the lung (F_{flow} in Equation 7) can be precisely reached.

The model can be used to quantify lung function and structure globally or in imaging experiments. Due to the relatively weak signal of dissolved Xenon, CSSR remains as an important tool in investigating lung function. However, imaging of dissolved Xenon has become quite feasible thanks to the rapid development of MRI technology. It should be noted that in either global or imaging experiments, in order to correctly use the model presented herein, it is important that the dissolved-Xenon signals are properly normalized by the corresponding gas-phase Xenon signals. This is due to variations of Xenon polarization and the relatively rapid signal decay inside the lung during an experiment, the amplitude of a dissolved-Xenon signal is only meaningful when compared to the gas signal. Therefore, in order to perform spatially-localized measurements of the pulmonary parameters using MRI, signals of the gas and dissolved phases of Xenon should be simultaneously acquired.

In some embodiments, a minimum of five parameters characterizes Xenon uptake of both S_{TP}(t) and S_{RBC}(t). Each curve has three parameters that include the saturation, time constant, and the linear slope. The model described herein utilizes five because the two curves have the same time constant. It should be noted that all five parameters, namely, b, δ/d, η, T, and t_{X}, are shared between S_{TP}(t) and S_{RBC}(t). In other words, these two expressions are completely correlated. Therefore, data should be fitted simultaneously to these two expressions in order to obtain accurate results.

In practice, unless the shortest exchange time is equal or longer than the expected time constant, the second-order term, or sometimes even the higher-order terms, should not be omitted. As described herein, the higher-order terms represent time constants (T/n²) that are much shorter than the principle time constant (T) that are to be measured. Therefore, ignoring the higher-order terms will risk resulting in a seemingly short time constant, especially when a significant portion of data is within the principle time constant. The shorter time constant will subsequently lead to an overestimation of Xenon diffusion (D) using Equation 5. This overestimation is speculated to account for the septal thicknesses measured by CSSR that was consistently higher than measured in histology in a known study where such D value was used. Moreover, adding more terms in the expressions does not increase the number of fitting parameters, and, therefore, does not significantly increase fitting complexity. In this respect, the approach described herein is similar to the methods described in known publications and studies, where truncated sums are also used.

Although the model described herein is shown to be a valid characterization of Xenon uptake in the lung, it is possible to further expand it to take into account more realistic features of dissolved Xenon in lung parenchyma. Approximations used in developing the model include a single Ostwald solubility (λ) and a single diffusion coefficient (D) for dissolved Xenon in all three compartments (tissue membrane/barrier, RBC, plasma) in the lung. Different geometries can also be used to better represent resemble lung micro-structures. These expansions from the current model, however, will likely result in more parameters in the expressions, and will generally impose higher requirements on data quality.

Accurate measurements of the dissolved-Xenon signal amplitudes are crucial for reliable data fitting and parameter extraction. In most situations, the two dissolved-Xenon signals overlap each other. To determine the signal amplitude of one peak without the “contamination” from the other, the dissolved-Xenon signal is fit to the following sum of two Lorentzians (double-Lorentzian), as shown in Equation 15

$$F ( f ) = {\sum }_{l = 1 , 2} \frac{{A}_{l} exp ( - i {θ}_{l} )}{{w}_{l} + i ( f - {f}_{l} )} , \qquad [ 15 ]$$

In Equation 15, f is frequency, f₁ and f₂ are the peak positions, w, A/w, and θ represent signal width, height, and phase, respectively. To avoid complex fitting Equation 15 can be decomposed into the real and imaginary parts, as shown in Equations 16a and 16b below.

$$\begin{matrix}Re [ F ( f ) ] = {\sum }_{l = 1 , 2} {A}_{l} \frac{{w}_{l} cos {θ}_{l} - ( f - {f}_{l} ) sin {θ}_{l}}{{( f - {f}_{l} )}^{2} + {w}_{l}^{2}} , & [ 16 a ] \\ Im [ F ( f ) ] = {\sum }_{l = 1 , 2} - {A}_{l} \frac{{w}_{l} sin {θ}_{l} + ( f - {f}_{l} ) cos {θ}_{l}}{{( f - {f}_{l} )}^{2} + {w}_{l}^{2}} .. & [ 16 b ]\end{matrix}$$

A computer program, written in GUNPLOT, was developed to fit data from both real and imaginary channels to Equations 16a and Equations 16b, respectively, and simultaneously, to extract the parameters Aₗ, θₗ, fₗ, and wₗ, l=1, 2. This procedure carries the same spirit as the simultaneous fitting described in the preceding section, since the real and imaginary signals are completely correlated through the parameters they share. The amplitude of each signal can then be calculated by numerically integrating the real part of the corresponding Lorentzian at phase 0.

When the two dissolved-Xenon peaks are very close in frequency, only real part of the signal needs to be fitted after appropriate phase correction, as shown in Equation 17 below.

$$F ( f ) = {\sum }_{l = 1 , 2} \frac{{a}_{l}}{{( f - {f}_{l} )}^{2} + {w}_{l}^{2}} . \qquad [ 17 ]$$

The same procedure for humans can be used to compute the amplitude of each dissolved-Xenon signal.

In situations where it is difficult to separate the two peaks of dissolved-Xenon signal, the entire dissolved-Xenon signal can be used to measure a subset of the pulmonary parameters described in the present disclosure. The approximate model for the entire dissolved-Xenon dynamics is presented in detail by known published tests. Since the two dissolved-Xenon peaks were not separated, Hct cannot be measured in this model; further, it ignores the air-blood barrier. Therefore this model is equivalent to the sum of S_{TP}(t) and S_{RBC}(t) with δ=0 in the present disclosure. Indeed, by adding Equations 11 and 12 together and setting δ=0, we recover exactly the expression for the entire dissolved-Xenon dynamics.

Several methods were proposed to fit one or both of the dissolved-Xenon signal amplitudes against gas-exchange time in previous published works. However, none of these methods were shown effective in quantifying all the pulmonary parameters described in the present disclosure.

The model of exchange and the corresponding processing method were tested by using previously published data in humans and comparing the pulmonary parameters thus measured with values found in known published works.

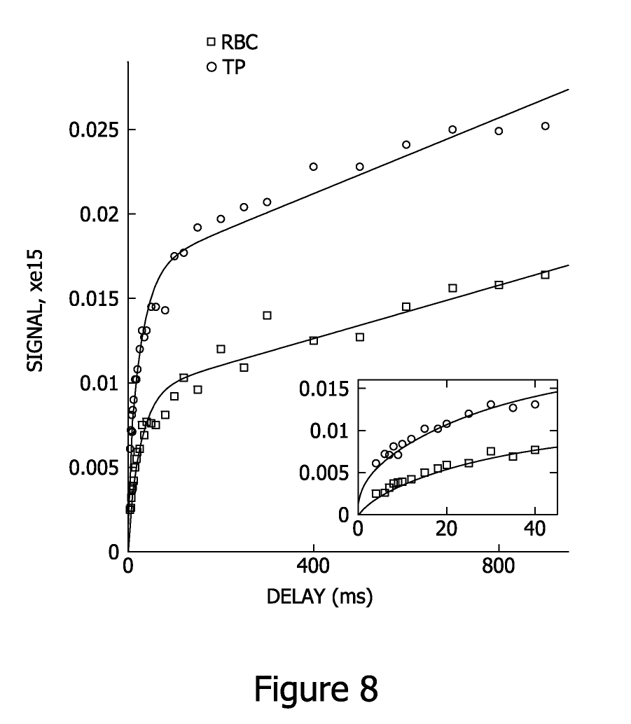

A representative plot of the Tissue+Plasma (TP)-Xenon signal and Red Blood Cell (RBC)-Xenon signal amplitudes versus exchange time from published data was fitted to Equations 11 and 12, respectively and simultaneously, is illustrated in FIG. 8. The inset demonstrates that the good fit between the model and data extends to the shortest exchange times.

The pulmonary parameters extracted from the fitting results, along with the corresponding values found in a known published literature, are listed in Table 1 (below).

TABLE 1
Pulmonary parameters and corresponding known values.

| | SVR (cm⁻¹) | δ/d | T (ms) | Hct | tₓ (s) |
|---|---|---|---|---|---|
| Xe08 | 170 | 0.106 | 35.5 | 0.15 | 1.46 |
| Xe09 | 209 | 0.18 | 11.2 | 0.212 | 0.86 |
| Xe11 | 130 | 0.019 | 35.8 | 0.21 | 0.888 |
| Xe15 | 272 | 0.06 | 29.5 | 0.25 | 1.252 |
| Xe17 | 270 | | 156 | 0.27 | 1.57 |
| Xe18 | 313 | 0.0285 | 102 | 0.27 | 1.876 |

The surface-area-to-volume ratio (SVR) was calculated from the fitting parameter b using Equation 8 and hematocrit (Hct) was calculated from the fitting parameter η using Equation 13. In evaluating these parameters, we used the following results: λ≠0.2 (0.18 in blood and 1.8 in lipids, and about 2% of lung made of lipids (20)), d≈5 μm, λ_{RBC}=0.19, and λ_{P}=0.09. Other known published values include SVR≈450 cm⁻¹, δ≈1 μm, Hct≈0.38, and t_{X}≈1 s.

As shown in Table 1, pulmonary parameters were measured by fitting the TP—Xenon signal and RBC—Xenon signal amplitudes in human lungs to Equations 11 and 12, respectively and simultaneously. Values reported in known published works that were measured using different methods are also listed for comparison. SVR—surface-area-to-volume ratio; δ/d—barrier-to-septum ratio; T—xenon exchange time constant; Hct—hematocrit; t_{X}—pulmonary capillary transit time. The published value of T is not cited because of the large discrepancy in previous known publications. The published known values presented in the table or used in evaluating SVR and Hct are: λ˜0.2 (0.18 in blood and 1.8 in lipids, and about 2% of lung made of lipids), d≈5 μm, λ_{RBC}=0.19, λ_{P}=0.09, SVR≈450 cm⁻¹, δ≈1 μm, Hct≈0.38, and t_{X}≈1 s.

The excellent fit of the model described herein to data as shown in FIG. 8, as well as the good agreement between the measured pulmonary parameters and the published values as shown in Table 1, demonstrate the validity of the data processing method for HP ¹²⁹Xe MR in the lung. Thus, the embodiments described herein could potentially be used for diagnosing and/or screening various pulmonary diseases which are related to one or more of the pulmonary parameters listed in Table 1. For example, since COPD is characterized by airway expansion and tissue destruction, a lung with COPD usually has a decreased SVR. Moreover, an elevated barrier-to-septum ratio (δ/d) indicates thickening of the air-blood barrier, which is likely a result fibrosis.

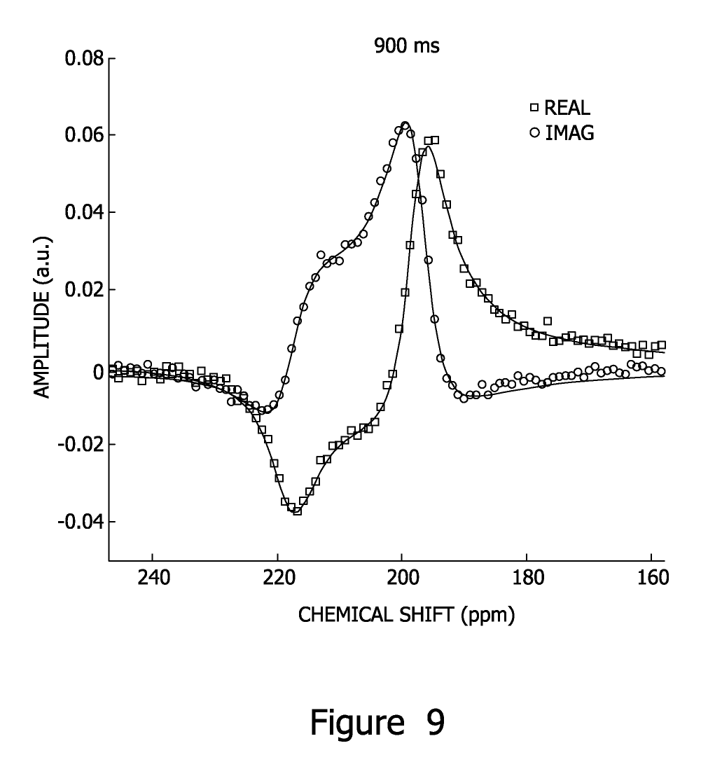

A plot of the dissolved-Xenon spectra in the real and imaginary channels in a human lung from published data, fitted using Equations 16a and 16b, respectively and simultaneously, is illustrated in FIG. 9. The excellent fit between the equations and data demonstrate the validity of Equation 15 for interpreting dissolved-Xenon signal in the human lung. The inset is a plot of the real spectrum with phase set to 0.

In summation, as compared to known techniques and theories that are used to measure gas exchange in the lung, embodiments described herein include systems and methods to quantify gas exchange in a lung using hyperpolarized Xenon gas by interpreting Xenon uptake dynamics for both dissolved-Xenon peaks in the lung. For example, the system may include a magnetic resonance imaging device configured to generate at least one spectroscopic signal representative of hyperpolarized Xenon gas within the lung, wherein the spectroscopic signal is at an amplitude of 197 ppm and/or 217 ppm. A computing device may be communicatively coupled to the magnetic resonance imaging device. The computing device may include a communication interface that is configured to receive the spectroscopic signal. A processor is coupled to the communication interface and is programmed to calculate at least one parameter related to an exchange of hyperpolarized Xenon gas in the lung based on the spectroscopic signal. The processor is programmed to calculate the parameter by comparing the spectroscopic signal with a period of time for a dispersion of hyperpolarized Xenon gas within the lung.

More specifically, embodiments described herein provide a model of gas exchange for hyperpolarized ¹²⁹Xe in the lung based on a simplified lung microstructure. The model provides a simple way to characterize uptake of Xenon at both resonance frequencies in the lung using parameters of essential importance in lung function and physiology. The model is consistent with existing data as well as existing theory which has been applied in known studies of lung diseases. The model can potentially be used to give comprehensive tests of the lung function and can be used to diagnose various pulmonary diseases.

Exemplary embodiments are described above in detail. The systems and methods are not limited to the specific embodiments described herein, but rather, components of the systems and/or steps of the methods may be utilized independently and separately from other components and/or steps described herein. For example, the systems may also be used in combination with other systems and methods, and is not limited to practice with only the systems as described herein. Rather, the exemplary embodiment can be implemented and utilized in connection with many other applications.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose aspects of the invention, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A computing device for use in a system for use in quantifying gas exchange in a lung, the computing device comprising:
a communication interface configured to receive at least one spectroscopic signal representative of hyperpolarized Xenon gas that is dissolved within at least one of lung tissue, blood plasma, and red blood cells, wherein the at least one spectroscopic signal resonates at a frequency of at least one of 197 ppm and 217 ppm;
a processor coupled to the communication interface and programmed to calculate at least one value that corresponds to a normalized amplitude of the at least one spectroscopic signal at a given gas-exchange time; and
a presentation interface coupled to the processor and configured to display at least one output representative of the at least one value to a user to enable a determination of a plurality of parameters related to gas exchange in the lung.

2. A computing device in accordance with claim 1, wherein the at least one spectroscopic signal includes a first spectroscopic signal that is representative of hyperpolarized Xenon gas within at least one of the lung tissue and the blood plasma that resonates at the frequency of 197 ppm and a second spectroscopic signal that is representative of hyperpolarized Xenon gas that is dissolved within the red blood cells at the frequency of 217 ppm.

3. A computing device in accordance with claim 2, wherein the processor is programmed to calculate a first value that corresponds to a normalized amplitude of the first signal and a second value that corresponds to a normalized amplitude of the second signal.

4. A computing device in accordance with claim 3, wherein the processor is further programmed to compare the first and second values with their respective normalized amplitudes to determine a plurality of pulmonary parameters that are shared between the first and second values.

5. A computing device in accordance with claim 3, wherein the processor is further programmed to compare the first and second values with their respective normalized amplitudes to determine at least one of a lung surface-area-to-volume ratio and a barrier-to-septum ratio.

6. A computing device in accordance with claim 3, wherein the processor is further programmed to compare the first and second values with their respective normalized amplitudes to determine at least one of a Xenon-exchange time constant and a pulmonary capillary time.

7. A computing device in accordance with claim 3, wherein the processor is further programmed to compare the first and second values with their respective normalized amplitudes to determine hematocrit levels.

8. A computing device in accordance with claim 1, wherein the processor is programmed to calculate the at least one value by using a spatial integration over at least one region of at least one of air-blood barriers in the lung and capillary blood in the lung.

9. A computing device in accordance with claim 1, wherein the processor is programmed to calculate the at least one value by using a temporal integration over a period of time during which capillary blood flows through the gas-exchange region in the lung.

10. A system for use in quantifying gas exchange in a lung, the system comprising:
a magnetic resonance imaging device configured to generate at least one spectroscopic signal representative of hyperpolarized Xenon gas that is dissolved within at least one of lung tissue, blood plasma, and red blood cells, wherein the at least one spectroscopic signal resonates at a frequency of at least one of 197 ppm and 217 ppm; and
a computing device communicatively coupled to the magnetic resonance imaging device, wherein the computing device comprises:
a communication interface configured to receive the at least one spectroscopic signal;
a processor coupled to the communication interface and programmed to calculate at least one value that corresponds to a normalized amplitude of the at least one spectroscopic signal at a given gas-exchange time; and
a presentation interface coupled to the processor and configured to display at least one output representative of the at least one value to a user to enable a determination of a plurality of parameters related to gas exchange in the lung.

11. A system in accordance with claim 10, wherein the at least one spectroscopic signal includes a first spectroscopic signal that is representative of hyperpolarized Xenon gas within at least one of the lung tissue and the blood plasma that resonates at the frequency of 197 ppm and a second spectroscopic signal that is representative of hyperpolarized Xenon gas that is dissolved within the red blood cells at the frequency of 217 ppm.

12. A system in accordance with claim 11, wherein the processor is programmed to calculate a first value that corresponds to a normalized amplitude of the first signal and a second value that corresponds to a normalized amplitude of the second signal.

13. A system in accordance with claim 12, wherein the processor is further programmed to compare the first and second values with their respective normalized amplitudes to determine a plurality of pulmonary parameters shared between the first and second values.

14. A system in accordance with claim 10, wherein the processor is programmed to calculate the at least one value by using a spatial integration over at least one region of at least one of air-blood barriers in the lung and capillary blood in the lung.

15. A system in accordance with claim 10, wherein the processor is programmed to calculate the at least one value by using a temporal integration over a period of time during which capillary blood flows through the gas-exchange region in the lung.

16. A method for quantifying gas exchange in a lung, the method comprising:
receiving, via a communication interface, at least one spectroscopic signal representative of hyperpolarized Xenon gas that is dissolved within at least one of lung tissue, blood plasma, and red blood cells, wherein the at least one spectroscopic signal resonates at a frequency of at least one of 197 ppm and 217 ppm;
calculating, via a processor, at least one value that corresponds to a normalized amplitude of the at least one spectroscopic signal at a given gas-exchange time; and
displaying at least one output that is representative of the at least one value to a user, via a presentation interface, to enable a determination of a plurality of parameters related to gas exchange in the lung.

17. A method in accordance with claim 16, receiving, via a communication interface, at least one spectroscopic signal further comprises receiving, via the communication interface, a first spectroscopic signal that is representative of hyperpolarized Xenon gas within at least one of the lung tissue and the blood plasma that resonates at the frequency of 197 ppm and a second spectroscopic signal that is representative of hyperpolarized Xenon gas that is dissolved within the red blood cells at the frequency of 217 ppm.

18. A method in accordance with claim 17, wherein calculating, via a processor, at least one value further comprises calculating, via the processor, a first value that corresponds to a normalized amplitude of the first signal and a second value that corresponds to a normalized amplitude of the second signal.

19. A method in accordance with claim 18, further comprising comparing, via the processor, the first and second values with their respective normalized amplitudes to determine a plurality of pulmonary parameters that are shared between the first and second values.

20. A method in accordance with claim 16, wherein calculating, via a processor, at least one value further comprises calculating, via the processor the at least one value by using a spatial integration over at least one region of at least one of air-blood barriers in the lung and capillary blood in the lung.
